(19) United States
(12) Patent Application Publication
(10) Pub. No.: US 2024/0368505 A1
(43) Pub. Date: Nov. 7, 2024

(54) FLUORINE-FREE CLEANING AGENT, PREPARATION METHOD THEREFOR AND USE THEREOF

(71) Applicant: TAN KAH KEE INNOVATION LABORATORY, Xiamen (CN)

(72) Inventors: Aiqiang Zhang, Xiamen (CN); Ting Chen, Xiamen (CN); Mark Neisser, Xiamen (CN); Congjie Lu, Xiamen (CN); Songsong Luo, Xiamen (CN); Weishun Lai, Xiamen (CN)

(21) Appl. No.: 18/774,234

(22) Filed: Jul. 16, 2024

Related U.S. Application Data
(63) Continuation of application No. PCT/CN2022/072276, filed on Jan. 17, 2022.

(51) Int. Cl. C11D 7/50; C11D 7/08; C11D 7/26; C11D 7/32; C11D 7/34; H01L 21/02

(52) U.S. Cl. CPC C11D 7/5022; C11D 7/08; C11D 7/261; C11D 7/264; C11D 7/268; C11D 7/3209; C11D 7/3218; C11D 7/3281; C11D 7/34; C11D 7/5009; H01L 21/02057

(57) ABSTRACT

A fluorine-free cleaning agent is a water-based cleaning agent. The fluorine-free cleaning agent comprises of water, organic solvent and amine compound, wherein the mass of the organic solvent is 15-85% of the mass of the fluorine-free cleaning agent; and the mass of the amine compound is 5-50% of the mass of the fluorine-free cleaning agent. The fluorine-free cleaning agent further comprises of one or more of corrosion inhibitor, acid compound and alcohol compound. By means of a synergistic effect of the specific amine compound and one or more of corrosion inhibitor, acid and alcohol, the fluorine-free cleaning agent provided in the present disclosure showed good cleaning capability even without fluoride by comparing with the prior art.

### CROSS REFERENCE TO RELATED APPLICATIONS

This application is a continuation of International Application No. PCT/CN2022/072276, filed Jan. 17, 2022, which is hereby incorporated by reference in its entirety.

### TECHNICAL FIELD

The present disclosure belongs to the technical field of electronic industry, and especially, it relates to a fluorine-free cleaning agent, preparation method therefor and use thereof.

### BACKGROUND OF THE INVENTION

Manufacturing of integrated circuit chip is a key link in the downstream of semiconductor industrial chain. With the reduction of critical dimension of integrated circuits, the process requirements for manufacturing are also higher. The removal of residues on the wafer surface after dry etching or ashing processes is an essential technique to ensure the steady conduction of following process, also to guarantee the performance, yield and reliability of produced chip.

Etching process takes an important role in transferring patterns after lithography, the etched material could be metal or dielectric layer, like aluminum, silicon dioxide, silicon nitride, and so on. After the introduction of patterns, a large amount of photoresist, metal-organic complexes, inorganic oxides and other residues generated on wafer surface, which affect in the proceeding of following processes. The remained residues need to be removed by a special cleaning agent. To ensure the cleanliness and integrity of the wafer substrate, the cleaning agent is required to completely remove all the residues without attack or damage to other materials, including metal and dielectric layers.

With the development of integrated circuits technique, the cleaning agents for removing residues on wafer surface after etching process, are also being updated. The fluorine-containing cleaning agent has the advantage of aggressive removal capability, but the existence of a fluoride brings a risk of corrosion to substrate, which is easy to cause the formation of defects. Actually, in some cases of production, it is also found that the use of the fluorine-containing cleaning agent could cause some reliability issues in chips. This is because after cleaning, a few fluoride tends to remain on wafer surface even after post rinse, the remained fluoride further reacts with the wafer substrate to produce by-products such as aluminum fluoride. The generated by-products are difficult to remove, resulting in the decreasing of chip yield and some other quality problems. In addition, the fluorine-containing cleaning agent also has higher requirements on safety and equipment, which leads to high production cost.

Many manufactures are developing fluorine-free cleaning agents, however, current fluorine-free technology has some shortcomings such as long cleaning time, high operation temperature, poor residue removal capability or short service life and so on. Furthermore, there is no fluorine-free cleaner able to remove different types of post-etch residues. Therefore, the key strategy to enhance product competitiveness in the rapidly developing semiconductor industry is to develop a novel fluorine-free post-etch residue removal, with the characteristics of high clean capability, long lifetime, short process time, safe and simple operation process and reasonable cost of ownership.

### SUMMARY OF THE INVENTION

In view of this, the technical problem to be solved by the present disclosure is to provide a fluorine-free cleaning agent with low cleaning temperature and high cleaning capability, preparation method therefor and use thereof.

The present disclosure provides a fluorine-free cleaning agent, which is a water-based cleaning agent; the fluorine-free cleaning agent comprises water, an organic solvent and an amine compound;
the mass of the organic solvent is 15%-85% of that of the fluorine-free cleaning agent;
the mass of the amine compound is 5%-50% of that of the fluorine-free cleaning agent;
the agent also comprises one or more selected from the group consisting of a corrosion inhibitor, an acid and an alcohol compound.

Preferably, the mass of the corrosion inhibitor is 0.1%-10% of that of the fluorine-free cleaning agent;
the mass of the acid is 0.5%-5% of that of the fluorine-free cleaning agent;
the mass of the alcohol compound is 0.5%-10% of that of the fluorine-free cleaning agent;
the alcohol compound is a dihydric alcohol compound and/or a polyhydric alcohol compound.

Preferably, the corrosion inhibitor at least comprises one of a triazole group, an amino group, a hydroxyl group, a carboxyl group or a sulfhydryl group; the acid is one or more selected from the group consisting of sulfuric acid, nitric acid, hydrochloric acid, phosphoric acid, formic acid, acetic acid, citric acid, boric acid and carbonic acid; the alcohol compound is one or more selected from the group consisting of ethylene glycol, glycerol, 1,3-butanediol, 1,2-pentanediol, pentaerythritol, 2,5-hexanediol, polycaprolactone diol, 1,6-hexanediol, sorbitol, neopentyl glycol, 1,4-butanediol, 1,2,6-hexanetriol, xylitol, L-mannitol, D(+)-arabitol, geraniol, dulcitol, 1,2,4-butanetriol, furfuryl alcohol, phytol, dipentaerythritol, L-threitol, L-talitol, glucose, erythritol, xylose etc.

Preferably, the corrosion inhibitor is one or more selected from the group consisting of 1,2,4-triazole, benzotriazole, 1H-1,2,3-triazole, 5-methylbenzotriazole, 5-hydroxybenzotriazole, 1H-1,2,3-triazole-1-amine, 3-cyano-1,2,4-triazole, 1,2,4-triazole-3-carboxamide, 1-ethyl-1H-1,2,3-triazole, 1-phenyl-1H-1,2,4-triazole, 1H-1,2,4-triazole-3-carboxylic acid, 2-phenyl-2H-1,2,3-triazole, 3-methyl-1H-1,2,4-triazole, 3-phenyl-1,2,4-1H-triazole, 4-methyl-1H-1,2,3-triazole, 1H-1,2,3-triazole-4-carboxylic acid, 2H-2-acetic acid-1,2,3-triazole, 3,5-diamino-1,2,4-triazole, methyl 1,2,3-triazole-4-carboxylate, methyl1,2,4-triazole-3-carboxylate, N,N′-carbonylbis(1,2,3-triazole), 1,4-dimethyl-1H-1,2,3-triazole, methyl 2H-1,2,3-triazole-4-carboxylate, 3,5-diphenyl-1H-1,2,4-triazole, 5-methyl-1H-1,2,4-triazole-3-thiol, 3-amino-5-mercapto-1,2,4-triazole, 3-(1,2,4-triazol-1-yl) benzoic acid, 3-(1,2,4-triazol-1-yl) benzaldehyde, 4-(4H-1,2,4-triazol-3-yl) aniline, 1-hydroxybenzotriazole, 3-(1H-(1,2,3) triazol-4-yl)-benzonitrile, 3-mercapto-1,2,4-triazole, 3-amino-1,2,4-triazole, 3-amino-1H-1,2,4-triazole-5-carboxylic acid, 4-(4H-1,2,4-triazol-4-yl) benzoic acid, 1-hydroxy-7-azobenzotriazole, [1,2,4] triazole [1,5-a] pyridine-6-formaldehyde, [1,2,4] triazolo [1,5-a] pyridine-7-ol, 1-methyl-1,2,3-triazole-5-carboxylic acid methyl ester, 5-cyclohexyl-1H-3-amino-1,2,4-triazole, 4-amino-4H-1,2,4-triazole, 5-amino-2,4-dihydro-[1,2,4] triazol-3-one, 4,5,6,7-tetrahydro-1,2,3-triazolo [1,5-a] pyrazine, 2-mercaptopyridine, 2-mercaptopyrazine, 2-mercaptoimidazole, 2-mercaptothiazole, 2-mercaptonicotinic acid, 3-mercaptobutyric acid, 3-mercaptopropionic acid, 3-mercaptoindole, 4-mercaptopyridine, 4-mercaptouridine, 6-mercaptopurine, 6-mercaptohexanoic acid, beta-mercaptoethylamine, dimercaprol, thionicotinamide, 1,5-dimercaptonaphthalene, 2-mercapto-3-butanol, 2-mercapto-3-pentanone, 2-mercaptothiazoline, 2-mercaptobenzyl alcohol, 2-methylmercaptoaniline, 3-mercapto-1-hexanol, 3-mercapto-2-butanone, 3-mercapto-2-pentanone, 2-mercaptobenzoic acid, 3-mercaptobenzoic acid, 4-mercaptobenzoic acid, 4-mercaptobenzyl alcohol, 4-mercaptobenzaldehyde, 6-mercaptohexan-1-ol, 6-methylmercaptopurine, 2,4-dimercaptopyrimidine, 2,6-dimercaptopurine, 2-mercaptobenzimidazole, 2-mercaptobenzothiazole, 2-mercaptobenzoxazole, 4-mercaptophenylacetic acid, 3-mercaptohexyl acetate, 3-mercapto-1,2,4-triazole, o-aminophenol, catechol, dopamine, 4-ethylcatechol, 3,4-dihydroxybenzoic acid, nordihydroguaiaretic acid, 2,3-dihydroxypyridine, 2,4-dihydroxyquinoline, 3,4-dihydroxyacetophenone, 2,3-dihydroxyquinoxaline, 3,4-dihydroxybenzonitrile, 1,2-dihydroxynaphthalene, 3,4-dihydroxybenzaldehyde, 5,6-dihydroxyindole, 4-amino-6-hydroxy-2-mercaptopyrimidine, 2-methylmercapto-4-amino-6-hydroxypyrimidine, 2-mercaptobenzyl alcohol, 2-mercaptocytosine, 6-mercapto-1-hexanol, 6-amino-2-mercaptopyrimidine-4-ol, 3-mercapto-1-hexanol, thiosalicylic acid, 3-mercapto-1-propanol, 3-mercaptopropionic acid, 2-mercapto-5-methylbenzimidazole, 4,6-dimethyl-2-mercaptopyrimidine, 3-mercapto-3-methyl-1-butanol, 3-mercapto-4-methyl-4H-1,2,4-triazole, 5-methoxy-2-mercaptobenzimidazole, 3-mercaptophenylboronic acid, polyethylene glycol, polyimide, 2-phenyl-4-pentaethylenehexamine-2-ol, 3-amino-5-hydroxypyrazole, 2-amino-3-hydroxyphenazine, 4-amino-3-hydroxybenzoic acid, 3-amino-4-hydroxypyridine, 2′-amino-3′-hydroxyacetophenone, 5-amino-2-hydroxypyridine, 4-amino-6-hydroxypyrimidine, 2-amino-8-hydroxyquinoline, 2-amino-3-hydroxypyridine, 3′-amino-2′-hydroxybiphenyl-3-carboxylic acid, 2-amino-4-hydroxybenzothiazole, 2-acetamido-6-hydroxypurine, 2-amino-N-hydroxypropionamide, 2-amino-N-hydroxypentanamide, 3-amino-5-hydroxypyridine, 4-acetamido-3-hydroxybenzoic acid, 2-amino-4-hydroxy-6-methylpyrimidine etc.

Preferably, the amine compound is one or more selected from the group consisting of methylamine, ethylamine, hydroxylamine, octylamine, triethylamine, acetamide, diethylamine, tert-butylamine, butyramide, dopamine, isobutylamine, isoamylamine, n-propylamine, n-hexylamine, cyclopropylamine, cyclohexylamine, cycloheptylamine, cyclopentylamine, heptylamine, ethanolamine, diethanolamine, diglycolamine, isopropanolamine, triisopropanolamine, diisopropanolamine, N-ethylethanolamine, N-phenylethanolamine, N-acetylethanolamine, N-butyldiethanolamine, N-cyclohexylethanolamine, N-benzyldiethanolamine, N-phenyldiethanolamine, N,N-dibenzylethanolamine, N-tert-butyldiethanolamine, N-tert-butylisopropanolamine, N-methyldiisopropanolamine, 1,6-hexanediamine, 1,2-propanediamine, 1,3-propanediamine, 1,4-butanediamine, 1,8-octanediamine, triethylenediamine, tri-n-dodecylamine, diethylenetriamine, adipamide, maleic diamine, 2-octyldodecylamine, N-ethylethylenediamine, N-methylethylenediamine, N-benzylethylenediamine, N-phenylethylenediamine, spermine, N-acetylethylenediamine, pentaethylenehexamine, tetraethylenepentamine, 1H-pyrazole-3,5-diamine, 3-diethylaminopropylamine, 3-dimethylaminopropylamine, N-butylethylenediamine, N-isopropylethylenediamine, N-methyl-p-phenylenediamine, tetramethylmethanediamine, tetrabutylammonium hydroxide, tetraethylammonium hydroxide, tetrapropylammonium hydroxide, tetramethylammonium hydroxide, 2-[(hydroxymethyl) amino] ethanol, benzyltrimethylammonium hydroxide, N-(benzylcarbonyloxy) hydroxylamine and N,N-dibenzylhydroxylamine; the organic solvent is one or more selected from the group consisting of 2-methoxyethanol, 2-ethoxyethanol, 2-butoxyethanol, diethylene glycol monomethylether, butyldiglycol, dipropylene glycol butyl ether, tripropylene glycol butyl ether, 1-Methoxy-2-propyl acetate, N-methylpyrrolidone, N,N-dimethylformamide, N,N-dimethylacetamide, N,N-diethylpropionamide, N,N-dimethylpropionamide, N,N-diethylacetamide, sulfolane, dimethyl sulfoxide and 1,4-butyrolactone.

Preferably, a stabilizer is also comprised; the mass of the stabilizer is 2%-20% of that of the fluorine-free cleaning agent; the stabilizer is one or more selected from the group consisting of ethanol, 2-hydroxypyridine, 4-hydroxypyridine, p-hydroxybenzaldehyde, salicylic acid, thiosalicylic acid, 2,6-dimethyl-3-hydroxypyridine, 2,3-dihydroxypyridine, 5-amino-2-hydroxypyridine, gelatin, tris(hydroxymethyl) aminomethane, 3-morpholinopropanesulfonic acid, 4-hydroxyethylpiperazine ethanesulfonic acid, ammonium borate, ammonium acetate, ammonium formate, ammonium phosphate, ammonium dihydrogen phosphate, ammonium citrate and barbituric acid.

A surfactant is also comprised; the mass of the surfactant is 0.5%-10% of that of the fluorine-free cleaning agent; the surfactant is one or more selected from the group consisting of 3,5-dimethyl-1-hexyne-3-ol, laureth phosphate, coconut diethanolamide, cocamidopropyl betaine, cocamidopropyl hydroxysultaine, lauramidopropyl hydroxysultaine, acetoxime, lauramidopropyl amine oxide, monoglyceride, Span, dodecylbenzene sulfonic acid, polyoxyl-15 hydroxystearate etc.

Preferably, an antioxidant is also comprised; the mass of the antioxidant is 0.1%-10% of that of the fluorine-free cleaning agent; the antioxidant is one or more selected from the group consisting of butylated hydroxyanisole, 2,6-di-tert-butyl-p-cresol, hydroquinone, D-isoascorbic acid, sorbitol, phytic acid, chitosan and chitooligosaccharide.

The present disclosure also provides a preparation method for the fluorine-free cleaning agent, which comprises the step of:
mixing water, an organic solvent, an amine compound and one or more of a corrosion inhibitor, an acid and an alcohol compound to obtain the fluorine-free cleaning agent.

The present disclosure also provides use of the fluorine-free cleaning agent in the field of electronic industry including but not limited to semiconductor integrated circuits.

The present disclosure also provides a cleaning method, which comprises the following step: cleaning a wafer by a dipping (wet-bench) method or a single-wafer clean method using the fluorine-free cleaning agent.

The present disclosure provides a fluorine-free cleaning agent, which is a water-based cleaning agent; the fluorine-free cleaning agent comprises water, an organic solvent and an amine compound; the mass of the organic solvent is 15%-85% of that of the fluorine-free cleaning agent; the mass of the amine compound is 5%-50% of that of the fluorine-free cleaning agent; the fluorine-free cleaning agent also comprises one or more of a corrosion inhibitor, an acid and an alcohol compound. By means of a synergistic effect of the specific amine compound and one or more of corrosion inhibitor, acid and alcohol, the fluorine-free cleaning agent provided in the present disclosure showed good cleaning capability even without fluoride by comparing with the prior art. In addition, the fluorine-free cleaning agent owns the performance of reduced or prevented corrosion to metal and wafer substrate, and the reliability of a cleaned wafer is also improved. Compared with existing similar products, the cleaning agent provided in the present disclosure has the obvious advantages of reducing the cleaning temperature and the cleaning time with lower cost of ownership.

### BRIEF DESCRIPTION OF THE DRAWINGS

FIG. 1 is an SEM image of aluminum-etched wafer without cleaning;

FIG. 2 is an SEM image of aluminum-etched wafer cleaned by using the fluorine-free cleaning agent provided in Example 1 of the present disclosure;

FIG. 3 is an SEM image of aluminum-etched wafer cleaned by using the fluorine-free cleaning agent provided in Comparative Example 1;

FIG. 4 is an SEM image of silicon oxide etched wafer without cleaning;

FIG. 5 is an SEM image of silicon oxide etched wafer cleaned by using the fluorine-free cleaning agent provided in Example 7 of the present disclosure;

FIG. 6 is an SEM image of silicon oxide etched wafer cleaned by using the fluorine-free cleaning agent provided in Comparative Example 1;

FIG. 7 is an SEM image of silicon nitride etched wafer without cleaning;

FIG. 8 is an SEM image of silicon nitride etched wafer cleaned by using the fluorine-free cleaning agent provided in Example 7 of the present disclosure; and

FIG. 9 is an SEM image of silicon nitride etched wafer cleaned by using the fluorine-free cleaning agent provided in Comparative Example 1.

### DETAILED DESCRIPTION OF THE INVENTION

The technical solutions in the examples of the present disclosure will be clearly and completely described below with a combination of the examples of the present disclosure, and it is obvious that the described examples are only a part of the examples of the present disclosure, and not all of the examples. All other examples, which can be obtained by a person skilled in the art without making any creative effort based on the examples of the present disclosure, fall into the protection scope of the present disclosure.

The present disclosure provides a fluorine-free cleaning agent, which is a water-based cleaning agent; the fluorine-free cleaning agent comprises water, an organic solvent and an amine compound;
the mass of the organic solvent is 15%-85% of that of the fluorine-free cleaning agent;
the mass of the amine compound is 5%-50% of that of the fluorine-free cleaning agent;
the agent also comprises one or more of a corrosion inhibitor, an acid and an alcohol compound.

By means of a synergistic effect of the specific amine compound and one or more of the corrosion inhibitor, the acid and the alcohol, the fluorine-free cleaning agent provided in the present disclosure has a good cleaning capability even without fluoride. In addition, the fluorine-free cleaning agent owns the performance of reduced or prevented corrosion to metal and wafer substrate, and the reliability of a cleaned wafer is also improved. Compared with existing similar products, the cleaning agent provided in the present disclosure has the obvious advantages of reducing the cleaning temperature and the cleaning time with lower cost of ownership.

The pH value of the fluorine-free cleaning agent is preferably 7-13, and more preferably 7.9-13; in the examples provided by the present disclosure, the pH value of the fluorine-free cleaning agent is specifically 11.5, 11.8, 10.6, 11.7, 11.3, 12.8, 12.5, 12.7, 12.0, 13.0, 7.9, 10.5, 10.7, 8.6, 11.2, 11.1 or 8.0.

The fluorine-free cleaning agent provided in the present disclosure is a water-based cleaning agent; the cleaning agent comprises the organic solvent; the mass of the organic solvent is preferably 15%-85%, more preferably 15%-70%, and even more preferably 15%-60% of that of the fluorine-free cleaning agent; in the examples provided by the present disclosure, the mass of the organic solvent is specifically 15%, 25%, 60%, 35%, 38% or 40% of that of the fluorine-free cleaning agent; the organic solvent is not particularly limited as long as it is an organic solvent well known to those skilled in the art, and, in the present disclosure, preferably at least includes an alcohol ether organic solvent; the alcohol ether organic solvent is preferably one or more selected from the group consisting of 2-methoxyethanol, 2-ethoxyethanol, 2-butoxyethanol, diethylene glycol monomethylether, butyldiglycol, dipropylene glycol butyl ether and tripropylene glycol butyl ether; in the present disclosure, further preferably, the organic solvent is one or more selected from the group consisting of 2-methoxyethanol, 2-ethoxyethanol, 2-butoxyethanol, diethylene glycol monomethylether, butyldiglycol, dipropylene glycol butyl ether, tripropylene glycol butyl ether, 1-Methoxy-2-propyl acetate, N-methylpyrrolidone, N,N-dimethylformamide, N,N-dimethylacetamide, N,N-diethylpropionamide, N,N-dimethylpropionamide, N,N-diethylacetamide, sulfolane, dimethyl sulfoxide and 1,4-butyrolactone.

The fluorine-free cleaning agent provided in the present disclosure comprises the amine compound; the mass of the amine compound is preferably 5%-40% of that of the fluorine-free cleaning agent; in the examples provided by the present disclosure, the mass of the amine compound is specifically 15%, 25%, 22%, 50%, 5%, 32% or 40% of that of the fluorine-free cleaning agent; the amine compound is one or more selected from the group consisting of methylamine, ethylamine, hydroxylamine, octylamine, triethylamine, acetamide, diethylamine, tert-butylamine, butyramide, dopamine, isobutylamine, isoamylamine, n-propylamine, n-hexylamine, cyclopropylamine, cyclohexylamine, cycloheptylamine, cyclopentylamine, heptylamine, ethanolamine, diethanolamine, diglycolamine, isopropanolamine, triisopropanolamine, diisopropanolamine, N-ethylethanolamine, N-phenylethanolamine, N-acetylethanolamine, N-butyldiethanolamine, N,N-cyclohexylethanolamine, N-benzyldiethanolamine, N-phenyldiethanolamine, N-dibenzylethanolamine, N-tert-butyldiethanolamine, N-tert-butylisopropanolamine, N-methyldiisopropanolamine, 1,6-hexanediamine, 1,2-propanediamine, 1,3-propanediamine, 1,4-butanediamine, 1,8-octanediamine, triethylenediamine, tri-n-dodecylamine, diethylenetriamine, adipamide, maleic diamine, 2-octyldodecylamine, N-ethylethylenediamine, N-methylethylenediamine, N-benzylethylenediamine, N-phenylethylenediamine, spermine, N-acetylethylenediamine, pentaethylenehexamine, tetraethylenepentamine, 1H-pyrazole-3,5-diamine, 3-diethylaminopropylamine, 3-dimethylaminopropylamine, N-butylethylenediamine, N-isopropylethylenediamine, N-methyl-p-phenylenediamine, tetramethylmethanediamine, tetrabutylammonium hydroxide, tetraethylammonium hydroxide, tetrapropylammonium hydroxide, tetramethylammonium hydroxide, 2-[(hydroxymethyl) amino] ethanol, benzyltrimethylammonium hydroxide, N-(benzylcarbonyloxy) hydroxylamine and N,N-dibenzylhydroxylamine; in the present disclosure, further preferably, the amine compound includes an alcohol amine compound.

The fluorine-free cleaning agent provided in the present disclosure at least also comprises one or more of the corrosion inhibitor, the acid and the alcohol compound.

The corrosion inhibitor is added into the fluorine-free cleaning agent to reduce the corrosion of the cleaning agent to a metal, the mass of the corrosion inhibitor is preferably 0.5%-10%, more preferably 1%-7% and even more preferably 1%-5% of that of the fluorine-free cleaning agent; in the examples provided by the present disclosure, the mass of the corrosion inhibitor is specifically 1%, 4%, 2%, 5% or 10% of that of the fluorine-free cleaning agent; in the present disclosure, the corrosion inhibitor preferably at least comprises one of a triazole group, an amino group, group, a hydroxyl group, a carboxyl group or a mercapto group, and more preferably is one or more selected from the group consisting of 1,2,4-triazole, benzotriazole, 1H-1,2,3-triazole, 5-methylbenzotriazole, 5-hydroxybenzotriazole, 1H-1,2,3-triazole-1-amine, 3-cyano-1,2,4-triazole, 1,2,4-triazole-3-carboxamide, 1-ethyl-1H-1,2,3-triazole, 1-phenyl-1H-1,2,4-triazole, 1H-1,2,4-triazole-3-carboxylic acid, 2-phenyl-2H-1,2,3-triazole, 3-methyl-1H-1,2,4-triazole, 3-phenyl-1,2,4-1H-triazole, 4-methyl-1H-1,2,3-triazole, 1H-1,2,3-triazole-4-carboxylic acid, 2H-2-acetic acid-1,2,3-triazole, 3,5-diamino-1,2,4-triazole, methyl 1,2,3-triazole-4-carboxylate, methyl 1,2,4-triazole-3-carboxylate, N,N′-carbonylbis (1,2,3-triazole), 1,4-dimethyl-1H-1,2,3-triazole, methyl 2H-1,2,3-triazole-4-carboxylate, 3,5-diphenyl-1H-1,2,4-triazole, 5-methyl-1H-1,2,4-triazole-3-thiol, 3-amino-5-mercapto-1,2,4-triazole, 3-(1,2,4-triazol-1-yl) benzoic acid, 3-(1,2,4-triazol-1-yl) benzaldehyde, 4-(4H-1,2,4-triazol-3-yl) aniline, 1-hydroxybenzotriazole, 3-(1H-(1,2,3) triazol-4-yl)-benzonitrile, 3-mercapto-1,2,4-triazole, 3-amino-1,2,4-triazole, 3-amino-1H-1,2,4-triazole-5-carboxylic acid, 4-(4H-1,2,4-triazol-4-yl) benzoic acid, 1-hydroxy-7-azobenzotriazole, [1,2,4] triazole [1,5-a] pyridine-6-formaldehyde, [1,2,4] triazolo [1,5-a] pyridine-7-ol, 1-methyl-1,2,3-triazole-5-carboxylic acid methyl ester, 5-cyclohexyl-1H-3-amino-1,2,4-triazole, 4-amino-4H-1,2,4-triazole, 5-amino-2,4-dihydro-[1,2,4] triazol-3-one, 4,5,6,7-tetrahydro-1,2,3-triazolo [1,5-a] pyrazine, thiosalicylic acid, 2-mercaptopyridine, 2-mercaptopyrazine, 2-mercaptoimidazole, 2-mercaptothiazole, 2-mercaptonicotinic acid, 3-mercaptobutyric acid, 3-mercaptopropionic acid, 3-mercaptoindole, 4-mercaptopyridine, 4-mercaptouridine, 6-mercaptopurine, 6-mercaptohexanoic acid, beta-mercaptoethylamine, dimercaprol, thionicotinamide, 1,5-dimercaptonaphthalene, 2-mercapto-3-butanol, 2-mercapto-3-pentanone, 2-mercaptothiazoline, 2-mercaptobenzyl alcohol, 2-methylmercaptoaniline, 3-mercapto-1-hexanol, 3-mercapto-2-butanone, 3-mercapto-2-pentanone, 2-mercaptobenzoic acid, 3-mercaptobenzoic acid, 4-mercaptobenzoic acid, 4-mercaptobenzyl alcohol, 4-mercaptobenzaldehyde, 6-mercaptohexan-1-ol, 6-methylmercaptopurine, 2,4-dimercaptopyrimidine, 2,6-dimercaptopurine, 2-mercaptobenzimidazole, 2-mercaptobenzothiazole, 2-mercaptobenzoxazole, 4-mercaptophenylacetic acid, 3-mercaptohexyl acetate, 3-mercapto-1,2,4-triazole, o-aminophenol, catechol, dopamine, 4-ethylcatechol, 3,4-dihydroxybenzoic acid, nordihydroguaiaretic acid, 2,3-dihydroxypyridine, 2,4-dihydroxyquinoline, 3,4-dihydroxyacetophenone, 2,3-dihydroxyquinoxaline, 3,4-dihydroxybenzonitrile, 1,2-dihydroxynaphthalene, 3,4-dihydroxybenzaldehyde, 5,6-dihydroxyindole, 4-amino-6-hydroxy-2-mercaptopyrimidine, 2-methylmercapto-4-amino-6-hydroxypyrimidine, 2-mercaptobenzyl alcohol, 2-mercaptocytosine, 6-mercapto-1-hexanol, 6-amino-2-mercaptopyrimidine-4-ol, 3-mercapto-1-hexanol, 3-mercapto-1-propanol, 3-mercaptopropionic acid, 2-mercapto-5-methylbenzimidazole, 4,6-dimethyl-2-mercaptopyrimidine, 3-mercapto-3-methyl-1-butanol, 3-mercapto-4-methyl-4H-1,2,4-triazole, 5-methoxy-2-mercaptobenzimidazole, 3-mercaptophenylboronic acid, polyethylene glycol, polyimide, 2-phenyl-4-pentaethylenehexamine-2-ol, 3-amino-5-hydroxypyrazole, 2-amino-3-hydroxyphenazine, 4-amino-3-hydroxybenzoic acid, 3-amino-4-hydroxypyridine, 2′-amino-3′-hydroxyacetophenone, 5-amino-2-hydroxypyridine, 4-amino-6-hydroxypyrimidine, 2-amino-8-hydroxyquinoline, 2-amino-3-hydroxypyridine, 3′-amino-2′-hydroxybiphenyl-3-carboxylic acid, 2-amino-4-hydroxybenzothiazole, 2-acetamido-6-hydroxypurine, 2-amino-N-hydroxypropionamide, 2-amino-N-hydroxypentanamide, 3-amino-5-hydroxypyridine, 4-acetamido-3-hydroxybenzoic acid, 2-amino-4-hydroxy-6-methylpyrimidine etc.

In the fluorine-free cleaning agent provided by the present disclosure, the addition of the acid can improve the cleaning capability of the cleaning agent while reducing the metal etching rate in the same time. The mass of the acid is preferably 0.5%-5%, more preferably 1%-4%, even more preferably 2%-3.5%, and most preferably 2.5%-3% of that of the fluorine-free cleaning agent; in the examples provided by the present disclosure, the mass of the acid is specifically 2.8%, 3% or 2% of that of the fluorine-free cleaning agent; in the present disclosure, the acid, without particular limitation, may be an inorganic acid or an organic acid, and is preferably one or more selected from the group consisting of sulfuric acid, nitric acid, hydrochloric acid, phosphoric acid, formic acid, acetic acid, citric acid, boric acid and carbonic acid.

The action of the above acids will be described in detail below, taking boric acid and formic acid as examples.

As an inorganic small molecule boric acid, boric acid (H₃BO₃) is a weak acid, and plays a role in buffering the pH value of the fluorine-free cleaning agent. The sudden change of the pH value can easily cause corrosion of the solution to metals. Thus, boric acid can avoid the sudden change of the pH value caused by long-time use of the solution or water rinsing. Moreover, boric acid is an electron-rich compound, which has the ionization formula H₃BO₃+H₂O=H⁺+[B(OH)₄]⁻. Its ionized structure can form a stable four-coordinate complex with metal, oxide thereof, inorganic oxide etc. Taking metal aluminum as an example, a complex formed by boric acid and metal aluminum is adsorbed on the surface of aluminum to form a protective layer. Moreover, due to its small molecular structure, boric acid can make up for a protective layer gap formed after adsorption of a conventional corrosion inhibitor, and isolate the contact between aluminum and the solution to achieve the effect of corrosion resistance.

For residues on the wafer surface after dry-etching, agglomerated organic metal residues therein are hard to remove, so the residues usually need longer time or higher temperature to be completely cleaned. Due to its small molecular structure, boric acid can easily permeate into the organic metal residues, and some electron-rich centers thereof can attack the electron-deficient centers of the organic metal residues to promote the collapse of the residues, thereby being beneficial to improving the cleaning capability of the cleaning agent. Furthermore, boric acid H₃BO₃ is a water-soluble compound, and can avoid the residual organic matter, which is formed by such as organic boric acid derivatives, on the wafer surface after cleaning. Therefore, the wafer can be directly washed by water after being cleaned using the fluorine-free cleaning agent containing boric acid as acid.

Formic acid is an acid with a special structure. The structural formula of formic acid is

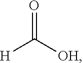

wherein one H is directly connected with a carboxyl —COOH, so formic acid has the properties of both acid and aldehyde. The above amine compound, especially hydroxylamine, can react with an aldehyde or ketone as follows:

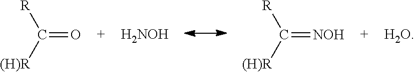

Thus, in some cleaning agent systems, formic acid can not only exert the properties of acid, but can also, due to the particularity of its structure, exert the properties of aldehyde to carry out a reaction with hydroxylamine like that mentioned above. Meanwhile, because formic acid has the properties of both acid and aldehyde, and the reaction of hydroxylamine therewith has a certain reversibility, in the course that the cleaning agent exerts the cleaning effect, a part of hydroxylamine can be gradually released from the reaction system of hydroxylamine and formic acid to continuously exert the cleaning effect. Hydroxylamine itself is unstable and volatile, whereas the reversible reaction of formic acid and hydroxylamine can effectively improve the stability of hydroxylamine in the cleaning agent, and reduce the volatilization during storage and use, thereby greatly improving the storage life of a hydroxylamine-based fluorine-free cleaning agent and the service life of the bath. Further, hydroxylamine, as a free base, can release some hydroxyl groups, which are liable to corrode metals, while a conventional corrosion inhibitor cannot effectively form a protective barrier to slow down the corrosion of hydroxyl groups to metals. By contrast, formic acid forms formate radicals in the cleaning agent, and the molecular stereo configuration of the formate radicals is matched with the metal lattice, so that a good complexing or coordination structure can be formed by the formate radicals and the metals on the wafer surface, and thus a barrier can be formed to isolate the direct contact between the solution and the metal surface, thereby reducing the corrosion to metals. Moreover, due to its small molecular structure, boric acid can make up for the cavity defects caused by a conventional corrosion inhibitor protective layer, and a compact protective layer can be formed on the metal surface through the synergistic action between formic acid and the corrosion inhibitor, thereby achieving the purpose of corrosion resistance. Therefore, the fluorine-free cleaning agent containing formic acid as acid not only has good cleaning effect and low corrosivity, but also simplifies the cleaning steps.

In the present disclosure, the mass of the alcohol compound is preferably 0.5%-10%, more preferably 1%-5%, and even more preferably 1%-4% of that of the fluorine-free cleaning agent, in the examples provided by the present disclosure, the mass of the alcohol compound is specifically 1%, 4%, 3% or 2% of that of the fluorine-free cleaning agent; the alcohol compound is preferably a dihydric alcohol compound and/or a polyhydric alcohol compound, and more preferably is one or more selected from the group consisting of ethylene glycol, glycerol, 1,3-butanediol, 1,2-pentanediol, pentaerythritol, 2,5-hexanediol, polycaprolactone diol, 1,6-hexanediol, sorbitol, neopentyl glycol, 1,4-butanediol, 1,2,6-hexanetriol, xylitol, L-mannitol, D(+)-arabitol, geraniol, dulcitol, 1,2,4-butanetriol, furfuryl alcohol, phytol, dipentaerythritol, L-threitol, L-talitol, glucose, erythritol, xylose etc.

The fluorine-free cleaning agent provided by the present disclosure preferably further comprises a stabilizer; the mass of the stabilizer is preferably 2%-20% of that of the fluorine-free cleaning agent; the stabilizer takes the function of adjusting the pH value of cleaning agent with good stability, and meanwhile, the stabilizer also has the effect of maintaining the consistency of the physical and chemical properties of the cleaning agent, which is helpful in prolonging the shelf life and bath life time. The stabilizer is preferably one or more selected from the group consisting of ethanol, 2-hydroxypyridine, 4-hydroxypyridine, p-hydroxybenzaldehyde, salicylic acid, thiosalicylic acid, 2,6-dimethyl-3-hydroxypyridine, 2,3-dihydroxypyridine, 5-amino-2-hydroxypyridine, gelatin, tris(hydroxymethyl) aminomethane, 3-morpholinopropanesulfonic acid, 4-hydroxyethylpiperazine ethanesulfonic acid, ammonium borate, ammonium acetate, ammonium formate, ammonium phosphate, ammonium dihydrogen phosphate, ammonium citrate and barbituric acid.

The fluorine-free cleaning agent provided by the present disclosure preferably further comprises a surfactant, which can promote the dispersibility and stability of each component in the cleaning agent. The mass of the surfactant is preferably 0.5%-10% of that of the fluorine-free cleaning agent; in the examples provided by the present disclosure, the mass of the surfactant is specifically 2% of that of the fluorine-free cleaning agent; the surfactant is one or more selected from the group consisting of 3,5-dimethyl-1-hexyne-3-ol, laureth phosphate, coconut diethanolamide, cocamidopropyl betaine, cocamidopropyl hydroxysultaine, lauramidopropyl hydroxysultaine, acetoxime, lauramidopropyl amine oxide, monoglyceride, span, dodecylbenzene sulfonic acid, polyoxyl-15 hydroxystearate etc.

The fluorine-free cleaning agent provided by the present disclosure preferably further comprises an antioxidant, which can improve the oxidation resistance and discoloration resistance of the cleaning agent. The mass of the antioxidant is preferably 0.1%-5% of that of the fluorine-free cleaning agent; in the examples provided by the present disclosure, the mass of the antioxidant is specifically 1% of that of the fluorine-free cleaning agent; the antioxidant is preferably one or more selected from the group consisting of butylated hydroxyanisole, 2,6-di-tert-butyl-p-cresol, hydroquinone, D-isoascorbic acid, sorbitol, phytic acid, chitosan and chitooligosaccharide.

The present disclosure also provides a preparation method for the fluorine-free cleaning agent, which comprises the following steps: mixing water, an organic solvent, an amine compound and one or more of a corrosion inhibitor, an acid and an alcohol compound to obtain the fluorine-free cleaning agent.

The sources of all raw materials in the present disclosure are not particularly limited and are commercially available. The water, the organic solvent, the amine compound and the corrosion inhibitor are the same as those mentioned above, and are not described herein again.

The present disclosure also provides use of the fluorine-free cleaning agent in the field of electronic industry including but not limited to semiconductor integrated circuits, and further preferably use of the fluorine-free cleaning agent for cleaning after etching process of semiconductor manufacturing. The etching processes may include the etching of metals, dielectric materials and inorganic media such as silicon, without special limitation. The fluorine-free cleaning agent in the present disclosure can be specifically used for cleaning residues after etching of metals such as aluminum, titanium and tantalum, and can also be used for cleaning residues after etching of dielectric layers such as silicon dioxide and silicon nitride. The types of the residues to be cleaned include but not limited to photoresist residues, inorganic residues, metal complex etc.

The present disclosure also provides a cleaning method using the fluorine-free cleaning agent, which comprises the following step: cleaning a wafer by a dipping (wet-bench) method or a single-wafer clean method using the fluorine-free cleaning agent.

In the present disclosure, the method specifically comprises the steps of dipping dry-etched wafer in the fluorine-free cleaning agent at a temperature of preferably 20° C.-70° C. and more preferably 25° C.-70° C., for a period of time of preferably 1 minute-60 minutes, more preferably 1 minute-40 minutes, still more preferably 1 minute-20 minutes and most preferably 1 minute-10 minutes, wherein the etched wafer is specifically one with a metal or inorganic medium material etched, for example, aluminum, titanium, tantalum, nickel, silicon dioxide, silicon nitride etc.; the wafer is then preferably post rinsed with ultrapure water etc., and then blow-drying with nitrogen to finish the cleaning.

In the present disclosure, the cleaning method using the fluorine-free cleaning agent can also be fulfilled by a single-wafer clean method, which specifically comprises the steps of rotating an etched wafer by means of a device such as spin coater, and dripping the fluorine-free cleaning agent and ultrapure water on the surface of the wafer for cleaning, wherein the rotating speed is 50-5000 rpm, the working temperature of the device is preferably 20° C.-70° C., and the cleaning time of the single-wafer clean method is 1 minute-60 minutes.

The fluorine-free cleaning agent provided by the present disclosure has a strong cleaning capability, and the cleaning temperature and cleaning time can be reduced.

In order to further illustrate the present disclosure, the following examples are provided to describe the fluorine-free cleaning agent, preparation method therefor and use thereof in detail.

The reagents used in the following examples are all commercially available.

### Example 1

15 wt % of monoethanolamine, 15 wt % of butyldiglycol, 1 wt % of D-sorbitol, 1 wt % of benzotriazole, 2 wt % of ethylene glycol and a balance of ultrapure water, in a total amount of 100 g, were added into a beaker one by one and shaken well, wherein solid reagents might be weighed firstly and then dissolved by adding a solvent.

### Example 2

25 wt % of monoethanolamine, 15 wt % of butyldiglycol, 1 wt % of D-sorbitol, 1 wt % of benzotriazole, 2 wt % of ethylene glycol and a balance of ultrapure water, in a total amount of 100 g, were added into a beaker one by one and shaken well, wherein solid reagents might be weighed firstly and then dissolved by adding a solvent.

### Example 3

15 wt % of monoethanolamine, 25 wt % of butyldiglycol, 1 wt % of D-sorbitol, 1 wt % of benzotriazole, 2 wt % of ethylene glycol and a balance of ultrapure water, in a total amount of 100 g, were added into a beaker one by one and shaken well, wherein solid reagents might be weighed firstly and then dissolved by adding a solvent.

### Example 4

15 wt % of monoethanolamine, 60 wt % of butyldiglycol, 1 wt % of D-sorbitol, 1 wt % of benzotriazole, 2 wt % of ethylene glycol and a balance of ultrapure water, in a total amount of 100 g, were added into a beaker one by one and shaken well, wherein solid reagents might be weighed firstly and then dissolved by adding a solvent.

### Example 5

10 wt % of monoethanolamine, 7 wt % of 1,3-propanediamine, 5 wt % of isopropanolamine, 25 wt % of butyldiglycol, 2.8 wt % of boric acid, 1 wt % of benzotriazole and a balance of ultrapure water, in a total amount of 100 g, were added into a beaker one by one and shaken well, wherein solid reagents might be weighed firstly and then dissolved by adding a solvent.

### Example 6

10 wt % of monoethanolamine, 12 wt % of 1,3-propanediamine, 25 wt % of butyldiglycol, 2.8 wt % of boric acid, 1 wt % of benzotriazole and a balance of ultrapure water, in a total amount of 100 g, were added into a beaker one by one and shaken well, wherein solid reagents might be weighed firstly and then dissolved by adding a solvent.

### Example 7

5 wt % of monoethanolamine, 17 wt % of 1,3-propanediamine, 35 wt % of butyldiglycol, 4 wt % of benzotriazole and a balance of ultrapure water, in a total amount of 100 g, were added into a beaker one by one and shaken well, wherein solid reagents might be weighed firstly and then dissolved by adding a solvent.

### Example 8

5 wt % of monoethanolamine, 17 wt % of 1,3-propanediamine, 60 wt % of butyldiglycol, 4 wt % of benzotriazole and a balance of ultrapure water, in a total amount of 100 g, were added into a beaker one by one and shaken well, wherein solid reagents might be weighed firstly and then dissolved by adding a solvent.

### Comparative Example 1

17 wt % of 1,3-propanediamine, 35 wt % of butyldiglycol, 4 wt % of benzotriazole and a balance of ultrapure water, in a total amount of 100 g, were added into a beaker one by one and shaken well, wherein solid reagents might be weighed firstly and then dissolved by adding a solvent.

### Comparative Example 2

5 wt % of monoethanolamine, 30 wt % of 1,3-propanediamine, 35 wt % of butyldiglycol, 1 wt % of benzotriazole and a balance of ultrapure water, in a total amount of 100 g, were added into a beaker one by one and shaken well, wherein solid reagents might be weighed firstly and then dissolved by adding a solvent.

The compositions of the fluorine-free cleaning agents provided in Example 1-Example 8 and Comparative Examples 1, 2 are shown in Table 1 and Table 2.

TABLE 1
Composition of the fluorine-free cleaning agents

| Cleaning agent (wt %) | Example 1 | Example 2 | Example 3 | Example 4 |
|---|---|---|---|---|
| D-sorbitol | 1 | 1 | 1 | 1 |
| Butyldiglycol | 15 | 15 | 25 | 60 |
| Benzotriazole | 1 | 1 | 1 | 1 |
| Monoethanolamine | 15 | 25 | 15 | 15 |
| Ethylene glycol | 2 | 2 | 2 | 2 |
| pH value | 11.5 | 11.8 | 11.5 | 10.6 |

TABLE 2
Composition of the fluorine-free cleaning agents

| | Example | Example | Example | Example | Comparative | Comparative |
|---|---|---|---|---|---|---|
| Cleaning agent (wt %) | 5 | 6 | 7 | 8 | Example 1 | Example 2 |
| Boric acid | 2.8 | 2.8 | 0 | 0 | 0 | 0 |
| Butyldiglycol | 25 | 25 | 35 | 60 | 35 | 35 |
| Benzotriazole | 1 | 1 | 4 | 4 | 4 | 1 |
| Monoethanolamine | 10 | 10 | 5 | 5 | 0 | 5 |
| Isopropanolamine | 5 | 0 | 0 | 0 | 0 | 0 |
| 1,3-Propanediamine | 7 | 12 | 17 | 17 | 17 | 30 |
| pH value | 11.7 | 11.3 | 12.8 | 12.5 | 11.8 | 12.5 |

Cleaning test of aluminum dry-etched wafers with the fluorine-free cleaning agents obtained in Example 1-Example 8 and Comparative Examples 1-2.

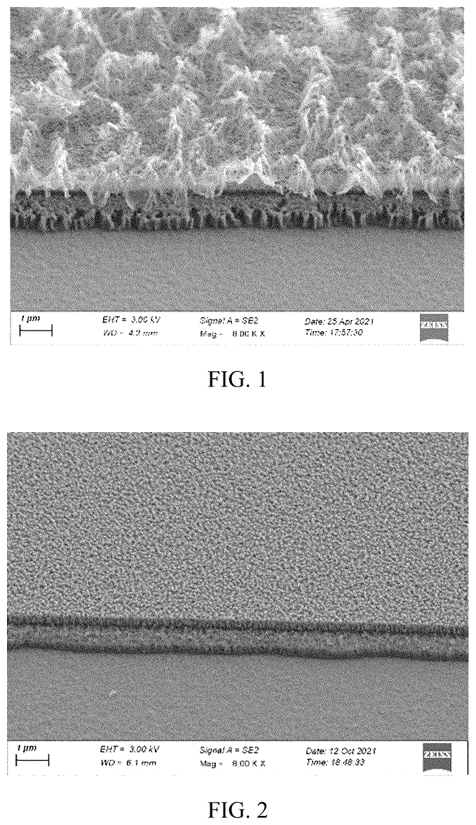

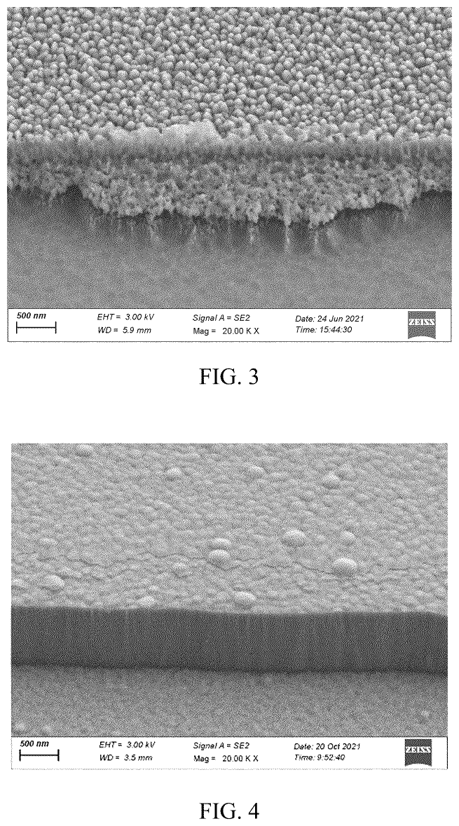

A wafer of aluminum-etched was dipped in the fluorine-free cleaning agents for 10 minutes at an experimental temperature of 70° C. After dipping, the test sample was taken out, washed with water and blow-dried with nitrogen immediately, and then the cleaning results was observed by scanning tunnel microscope SEM. The results are shown in Table 3 and FIG. 1-FIG. 3. Among them, FIG. 1 is an SEM image of aluminum-etched wafer without cleaning; FIG. 2 is an SEM image of aluminum-etched wafer cleaned by using the fluorine-free cleaning agent provided in Example 1 of the present disclosure; FIG. 3 is an SEM image of aluminum-etched wafer cleaned by using the fluorine-free cleaning agent provided in Comparative Example 1. From FIG. 3, it can be seen that there are residues on the wafer surface that are not completely removed. Particularly, in the present disclosure, after the cleaning by fluorine-free cleaning agent, wafer substrate is no longer need to be post rinsed by a solvent such as isopropanol, which can be directly washed by water, so that the operation process is simplified and the consumption of chemicals is saved.

TABLE 3
Cleaning test results of aluminum-etched wafers

| | Removal situation of residues on the surface |
|---|---|
| Cleaning agent | of the wafer after metallic aluminum etching |
| Example 1 | Completely removed |
| Example 2 | Completely removed |
| Example 3 | Completely removed |
| Example 4 | Completely removed |
| Example 5 | Completely removed |
| Example 6 | Completely removed |
| Example 7 | Completely removed |
| Example 8 | Completely removed |
| Comparative Example 1 | Not completely removed; for complete |
| | removal, the working temperature needs to be |
| | increased to 90° C. |
| Comparative Example 2 | Not completely removed |

Cleaning test of silicon dioxide etched wafers by fluorine-free cleaning agents were obtained in Example 5-Example 8 and Comparative Examples 1-2.

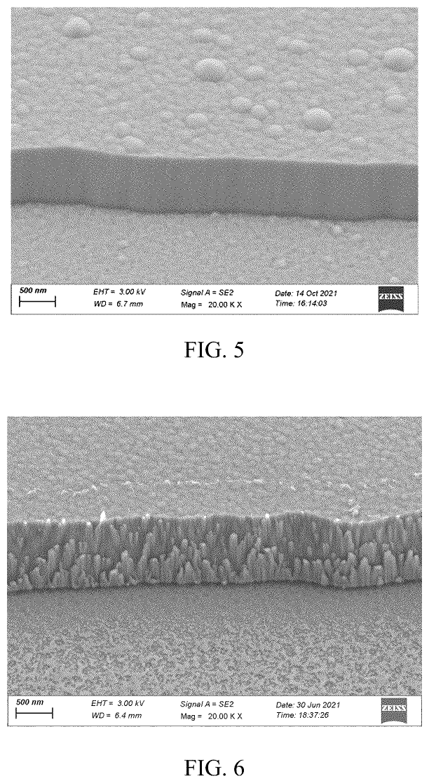

A silicon dioxide etched wafer was dipped in the fluorine-free cleaning agents for 10 minutes at an experimental temperature of 70° C. After dipping, the test sample was taken out, washed with water and blow-dried with nitrogen immediately, and then the cleaning result was observed by scanning tunnel microscope SEM. The results are shown in Table 4 and FIG. 4-FIG. 6. Among them, FIG. 4 is an SEM image of silicon dioxide etched wafer without cleaning; FIG. 5 is an SEM image of silicon dioxide etched wafer cleaned by using the fluorine-free cleaning agent provided in Example 7 of the present disclosure; FIG. 6 is an SEM image of silicon dioxide etched wafer cleaned by using the fluorine-free cleaning agent provided in Comparative Example 1.

TABLE 4
Cleaning test results of silicon dioxide etched wafers

| | | | | | Comparative | Comparative |
|---|---|---|---|---|---|---|
| Cleaning agent | Example 5 | Example 6 | Example 7 | Example 8 | Example 1 | Example 2 |
| Removal | Completely | Completely | Completely | Completely | Not completely | Completely |
| situation of | removed | removed | removed | removed | removed | removed |
| residues on | | | | | | |
| the surface | | | | | | |
| of the wafer | | | | | | |
| after silicon | | | | | | |
| dioxide etching | | | | | | |

Cleaning test of silicon nitride dry-etched wafers with the fluorine-free cleaning agents obtained in Example 7-Example 8 and Comparative Examples 1-2.

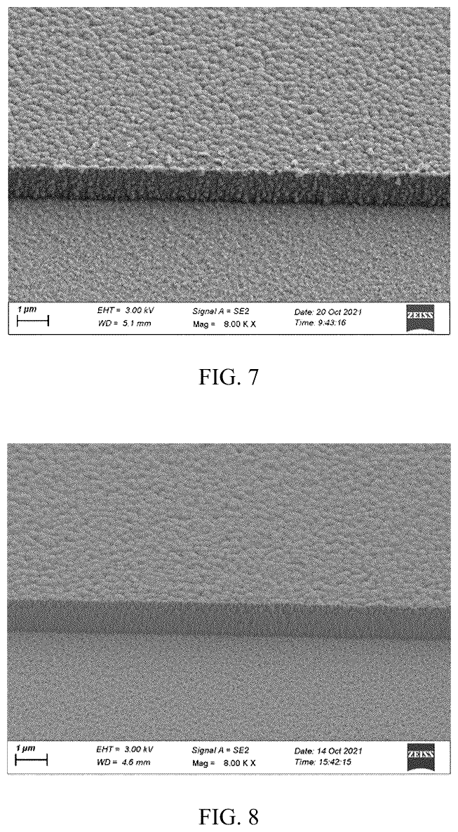

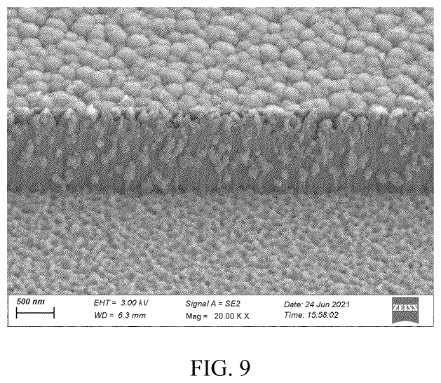

A silicon nitride etched wafer was dipped in the fluorine-free cleaning agents for 10 minutes at an experimental temperature of 70° C. After dipping, the test sample was taken out, washed with water and blow-dried with nitrogen immediately, and then the cleaning result was observed by scanning tunnel microscope SEM. The results are shown in Table 5 and FIG. 7-FIG. 9. Among them, FIG. 7 is an SEM image of silicon nitride etched wafer without cleaning; FIG. 8 is an SEM image of silicon nitride etched wafer cleaned by using the fluorine-free cleaning agent provided in Example 7 of the present disclosure; FIG. 9 is an SEM image of silicon nitride etched wafer cleaned by using the fluorine-free cleaning agent provided in Comparative Example 1. From FIG. 9, it can be seen that the wafer's sidewall is not completely cleaned.

TABLE 5
Cleaning results of silicon nitride etched wafers

| | | | Comparative | Comparative |
|---|---|---|---|---|
| Cleaning agent | Example 7 | Example 8 | Example 1 | Example 2 |
| Removal situation of | Completely | Completely | Not | Not |
| residues on the surface of | removed | removed | completely | completely |
| the wafer after silicon | | | removed | removed |
| nitride etching | | | | |

Corrosion test was evaluated by metal thin film:

An aluminum thin film was dipped in the fluorine-free cleaning agents obtained in Example 1, Example 5-Example 8 and Comparative Examples 1-2 for 15 minutes at an experimental temperature of 70° C. After dipping, the test sample was taken out, washed with water and blow-dried with nitrogen, and then the corrosion rate of the metal thin film was tested by a four-probe method and the corrosion result on the surface was observed by SEM. The results are shown in Table 6.

TABLE 6
Corrosion evaluation results of the metal thin film after cleaning

| | | | | | | Comparative | Comparative |
|---|---|---|---|---|---|---|---|
| Cleaning agent | Example 1 | Example 5 | Example 6 | Example 7 | Example 8 | Example 1 | Example 2 |
| Corrosion | <15 | <10 | <10 | <15 | <10 | <10 | >30 |
| rate −70° C. | | | | | | | |
| Surface | Partial | Almost no | Almost no | Partial | Almost no | Almost no | Severe |
| morphology | corrosion | corrosion | corrosion | corrosion | corrosion | corrosion | corrosion |
| of aluminum | | | | | | | |

The examples of the present disclosure deal with the use for etched wafers, wherein the thicknesses of aluminum, silicon dioxide and silicon nitride are each 1 micron, the aluminum is introduced into a wafer through plasma sputtering, and subjected to plasma dry etching by using chlorine and boron trichloride; the silicon dioxide and the silicon nitride are obtained through chemical vapor deposition method, and subjected to plasma dry etching by using fluorine-containing gas, oxygen and argon. The use of the fluorine-free cleaning agent according to the present disclosure includes but is not limited to the removal of residues on the wafer surface after dry etching. It can also be used for wafers after wet etching.

### Examples 9-13 and Comparative Examples 3-4

The fluorine-free cleaning agents of Examples 9-13 and Comparative Examples 3-4 were prepared according to the method described in the above examples and the composition formula shown in Table 7.

TABLE 7
Composition of the fluorine-free cleaning agents

| Cleaning | Example | Example | Example | Example | Example | Comparative | Comparative |
|---|---|---|---|---|---|---|---|
| agent (wt %) | 9 | 10 | 11 | 12 | 13 | Example 3 | Example 4 |
| Boric acid | 0 | 0 | 3 | 3 | 3 | 3 | 0 |
| Butyldiglycol | 35 | 0 | 35 | 35 | 0 | 0 | 35 |
| Dimethyl sulfoxide | 0 | 35 | 0 | 0 | 0 | 0 | 0 |
| Dimethylacetamide | 0 | 0 | 0 | 0 | 35 | 35 | 0 |
| 1,3-Propanediamine | 50 | 50 | 30 | 7 | 0 | 0 | 35 |
| Hydroxylamine | 0 | 0 | 15 | 15 | 0 | 0 | 15 |
| Tetramethylammonium | 0 | 0 | 0 | 0 | 5 | 0 | 0 |
| hydroxide | | | | | | | |
| Sorbitol | 4 | 4 | 4 | 0 | 2 | 2 | 4 |
| Thiosalicylic acid | 2 | 6 | 10 | 0 | 0 | 0 | 0 |
| Catechol | 0 | 0 | 0 | 2 | 10 | 10 | 0 |
| pH value | 12.0 | 13.0 | 7.9 | 10.5 | 12.3 | 10.7 | 13.8 |

The cleaning capability and corrosion rate of the fluorine-free cleaning agents obtained in Examples 9-13 were tested by the test methods described in the above examples. The results are shown in Tables 8 and 9.

TABLE 8
Cleaning capability test results of the fluorine-free cleaning agents obtained in Examples 9-13

| Cleaning | Example | Example | Example | Example | Example | Comparative | Comparative |
|---|---|---|---|---|---|---|---|
| agent | 9 | 10 | 11 | 12 | 13 | Example 3 | Example 4 |
| Removal | Completely | Completely | Completely | Completely | Completely | Not | Completely |
| situation of | removed | removed | removed | removed | removed | completely | removed |
| residues on | | | | | | removed | |
| the surface | | | | | | | |
| of the | | | | | | | |
| wafer after | | | | | | | |
| metallic | | | | | | | |
| aluminum | | | | | | | |
| etching | | | | | | | |
| Removal | Completely | Completely | Completely | Completely | Completely | Not | Completely |
| situation of | removed | removed | removed | removed | removed | completely | removed |
| residues on | | | | | | removed | |
| the surface | | | | | | | |
| of the | | | | | | | |
| wafer after | | | | | | | |
| silicon | | | | | | | |
| nitride | | | | | | | |
| etching | | | | | | | |
| Removal | Completely | Completely | Completely | Completely | Completely | Not | Completely |
| situation of | removed | removed | removed | removed | removed | completely | removed |
| residues on | | | | | | removed | |
| the surface | | | | | | | |
| of the | | | | | | | |
| wafer after | | | | | | | |
| silicon | | | | | | | |
| dioxide | | | | | | | |
| etching | | | | | | | |

TABLE 9
Corrosion rate test results of the fluorine-free cleaning agents obtained in Examples 9-13

| Cleaning | Example | Example | Example | Example | Example | Comparative | Comparative |
|---|---|---|---|---|---|---|---|
| agent | 9 | 10 | 11 | 12 | 13 | Example 3 | Example 4 |
| Corrosion | <3 | <1 | <6 | <1 | <1 | <20 | >30 |
| rate −70° C. | | | | | | | |
| Surface | Almost no | Almost no | Almost no | Almost no | Almost no | Partial | Severe |
| morphology | corrosion | corrosion | corrosion | corrosion | corrosion | corrosion | corrosion |
| of | | | | | | | |
| aluminum | | | | | | | |

### Example 14-18

The fluorine-free cleaning agents of Examples 14-18 and Comparative Examples 5-6 were prepared according to the method described in the above examples and the composition formula shown in Table 10.

TABLE 10
Composition of the fluorine-free cleaning agents

| Cleaning agent | Example | Example | Example | Example | Example | Comparative | Comparative |
|---|---|---|---|---|---|---|---|
| (wt %) | 14 | 15 | 16 | 17 | 18 | Example 5 | Example 6 |
| Formic acid | 2 | 0 | 0 | 0 | 2 | 0 | 2 |
| Boric acid | 0 | 2 | 2 | 2 | 0 | 0 | 0 |
| Dimethyl sulfoxide | 0 | 0 | 0 | 40 | 40 | 40 | 40 |
| Dimethylacetamide | 40 | 0 | 0 | 0 | 0 | 0 | 0 |
| N-methyl pyrrolidone | 0 | 40 | 40 | 0 | 0 | 0 | 26 |
| Hydroxylamine | 20 | 0 | 0 | 0 | 20 | 20 | 0 |
| Tetramethylammonium | 1 | 0 | 0 | 0 | 1 | 1 | 0 |
| hydroxide | | | | | | | |
| Triethylamine | 0 | 20 | 0 | 0 | 0 | 0 | 0 |
| Ethanolamine | 0 | 10 | 0 | 0 | 0 | 0 | 0 |
| Diethylenetriamine | 0 | 0 | 20 | 0 | 0 | 0 | 0 |
| Triethylenetetramine | 0 | 0 | 0 | 20 | 0 | 0 | 0 |
| Ethylene glycol | 2 | 0 | 0 | 0 | 2 | 2 | 2 |
| Glucose | 0 | 2 | 2 | 2 | 0 | 0 | 0 |
| 1,2,3-Triazole | 5 | 0 | 0 | 0 | 5 | 0 | 5 |
| Catechol | 0 | 3 | 3 | 3 | 0 | 0 | 0 |
| p-Hydroxy benzaldehyde | 2 | 0 | 0 | 0 | 2 | 2 | 2 |
| acetoxime | 2 | 0 | 0 | 0 | 0 | 0 | 0 |
| Span | 0 | 2 | 2 | 2 | 0 | 0 | 0 |
| Dodecylbenzene | 0 | 0 | 0 | 0 | 2 | 2 | 2 |
| sulfonic acid | | | | | | | |
| Hydroquinone | 1 | 0 | 0 | 0 | 0 | 0 | 0 |
| butylated hydroxyanisole | 0 | 1 | 1 | 1 | 0 | 0 | 0 |
| 2,6-di-tert-butyl-p-cresol | 0 | 0 | 0 | 0 | 1 | 1 | 1 |
| pH value | 8.6 | 11.2 | 11.3 | 11.1 | 8.0 | 13.5 | 11.2 |

The cleaning capability and corrosion rate of the fluorine-free cleaning agents obtained in Examples 14-18 and Comparative Example 5-6 were tested by the test methods described in the above examples. The results are shown in Tables 11 and 12.

TABLE 11
Corrosion rate test results of the fluorine-free cleaning agents
obtained in Examples 14-18 and Comparative Example 5-6

| Cleaning | Example | Example | Example | Example | Example | Comparative | Comparative |
|---|---|---|---|---|---|---|---|
| agent | 14 | 15 | 16 | 17 | 18 | Example 5 | Example 6 |
| Corrosion | <1 | <6 | <6 | <5 | <1 | >30 | <1 |
| rate −70° C. | | | | | | | |
| Surface | Almost no | Almost no | Almost no | Almost no | Almost no | Severe | Almost no |
| morphology | corrosion | corrosion | corrosion | corrosion | corrosion | corrosion | corrosion |
| of | | | | | | | |
| aluminum | | | | | | | |

TABLE 12
Cleaning capability test results of the fluorine-free cleaning
agents obtained in Examples 14-18 and Comparative Example 5-6

| Cleaning | Example | Example | Example | Example | Example | Comparative | Comparative |
|---|---|---|---|---|---|---|---|
| agent | 14 | 15 | 16 | 17 | 18 | Example 5 | Example 6 |
| Removal | Completely | Completely | Completely | Completely | Completely | Completely | Not |
| situation of | removed | removed | removed | removed | removed | removed | completely |
| residues on | | | | | | | removed |
| the surface | | | | | | | |
| of the | | | | | | | |
| wafer after | | | | | | | |
| metallic | | | | | | | |
| aluminum | | | | | | | |
| etching | | | | | | | |
| Removal | Completely | Completely | Completely | Completely | Completely | Completely | Not |
| situation of | removed | removed | removed | removed | removed | removed | completely |
| residues on | | | | | | | removed |
| the surface | | | | | | | |
| of the | | | | | | | |
| wafer after | | | | | | | |
| silicon | | | | | | | |
| nitride | | | | | | | |
| etching | | | | | | | |
| Removal | Completely | Completely | Completely | Completely | Completely | Completely | Not |
| situation of | removed | removed | removed | removed | removed | removed | completely |
| residues on | | | | | | | removed |
| the surface | | | | | | | |
| of the | | | | | | | |
| wafer after | | | | | | | |
| silicon | | | | | | | |
| dioxide | | | | | | | |
| etching | | | | | | | |

### Example 19-41

The fluorine-free cleaning agents of Examples 19-41 were prepared according to the method described in the above examples and the composition formula shown in Table 13-16.

TABLE 13
Composition of the fluorine-free cleaning agents

| | Example | Example | Example | Example | Example |
|---|---|---|---|---|---|
| Cleaning agent (wt %) | 19 | 20 | 21 | 22 | 23 |
| Boric acid | 3 | 3 | 3 | 3 | 3 |
| Butyldiglycol | 35 | 35 | 35 | 35 | 35 |
| Dimethyl sulfoxide | 0 | 0 | 0 | 0 | 0 |
| Dimethylacetamide | 0 | 0 | 0 | 0 | 0 |
| 1,3-Propanediamine | 7 | 7 | 7 | 7 | 7 |
| Hydroxylamine | 15 | 15 | 15 | 15 | 15 |
| Tetramethylammonium | 0 | 0 | 0 | 0 | 0 |
| hydroxide | | | | | |
| Sorbitol | 0 | 0 | 0 | 0 | 0 |
| Thiosalicylic acid | 0 | 0 | 0 | 0 | 0 |
| Benzotriazole | 2 | 0 | 0 | 0 | 0 |
| 1,5- | 0 | 2 | 0 | 2 | 0 |
| dimercaptonaphthalene | | | | | |
| polyethylene glycol | 0 | 0 | 2 | 2 | 0 |
| polyimide | 0 | 0 | 0 | 2 | 0 |
| 2-mercaptopyridine | 0 | 0 | 0 | 0 | 2 |

TABLE 14
Composition of the fluorine-free cleaning agents

| Cleaning agent | Example | Example | Example | Example | Example | Example |
|---|---|---|---|---|---|---|
| (wt %) | 24 | 25 | 26 | 27 | 28 | 39 |
| Boric acid | 3 | 3 | 3 | 3 | 3 | 3 |
| Butyldiglycol | 0 | 0 | 0 | 0 | 0 | 35 |
| Dimethyl sulfoxide | 0 | 0 | 0 | 0 | 0 | 0 |
| Dimethylacetamide | 35 | 35 | 35 | 35 | 35 | 0 |
| 1,3-Propanediamine | 0 | 0 | 0 | 0 | 0 | 7 |
| Hydroxylamine | 0 | 0 | 0 | 0 | 0 | 15 |
| Tetramethylammonium | 5 | 5 | 5 | 5 | 5 | 0 |
| hydroxide | | | | | | |
| Sorbitol | 2 | 2 | 2 | 2 | 2 | 0 |
| Ethylene glycol | 0 | 0 | 0 | 0 | 0 | 2 |
| Thiosalicylic acid | 0 | 0 | 0 | 0 | 0 | 0 |
| Catechol | 0 | 0 | 0 | 0 | 0 | 10 |
| Benzotriazole | 10 | 0 | 0 | 0 | 0 | 0 |
| 1,5-dimercaptonaphthalene | 0 | 10 | 0 | 0 | 0 | 0 |
| polyethylene glycol | 0 | 0 | 10 | 0 | 0 | 0 |
| polyimide | 0 | 0 | 0 | 10 | 0 | 0 |
| 2-mercaptopyridine | 0 | 0 | 0 | 0 | 10 | 0 |

TABLE 15
Composition of the fluorine-free cleaning agents

| Cleaning agent | Example | Example | Example | Example | Example | Example |
|---|---|---|---|---|---|---|
| (wt %) | 29 | 30 | 31 | 32 | 33 | 40 |
| Formic acid | 0 | 0 | 0 | 0 | 0 | 0 |
| Boric acid | 2 | 2 | 2 | 2 | 2 | 2 |
| Dimethyl sulfoxide | 0 | 0 | 0 | 0 | 0 | 0 |
| Dimethylacetamide | 0 | 0 | 0 | 0 | 0 | 0 |
| N-methyl pyrrolidone | 40 | 40 | 40 | 40 | 40 | 40 |
| Hydroxylamine | 0 | 0 | 0 | 0 | 0 | 0 |
| Tetramethylammonium | 0 | 0 | 0 | 0 | 0 | 0 |
| hydroxide | | | | | | |
| Triethylamine | 0 | 0 | 0 | 0 | 0 | 0 |
| Ethanolamine | 0 | 0 | 0 | 0 | 0 | 0 |
| Diethylenetriamine | 20 | 20 | 20 | 20 | 20 | 20 |
| Triethylenetetramine | 0 | 0 | 0 | 0 | 0 | 0 |
| Ethylene glycol | 0 | 0 | 0 | 0 | 0 | 2 |
| Glucose | 2 | 2 | 2 | 2 | 2 | 0 |
| 1,2,3-Triazole | 0 | 0 | 0 | 0 | 0 | 2 |
| Catechol | 0 | 0 | 0 | 0 | 0 | 3 |
| Benzotriazole | 3 | 0 | 0 | 0 | 0 | 0 |
| 1,5-dimercaptonaphthalene | 0 | 3 | | 0 | 0 | 0 |
| polyethylene glycol | 0 | 0 | 3 | 0 | 0 | 0 |
| polyimide | 0 | 0 | 0 | 3 | 0 | 0 |
| 2-mercaptopyridine | 0 | 0 | 0 | 0 | 3 | 0 |
| p-Hydroxy | 0 | 0 | 0 | 0 | 0 | 0 |
| benzaldehyde | | | | | | |
| acetoxime | 0 | 0 | 0 | 0 | 0 | 0 |
| Span | 2 | 2 | 2 | 2 | 2 | 2 |
| Dodecylbenzene | 0 | 0 | 0 | 0 | 0 | 0 |
| sulfonic acid | | | | | | |
| Hydroquinone | 0 | 0 | 0 | 0 | 0 | 0 |
| butylated | 1 | 1 | 1 | 1 | 1 | 1 |
| hydroxyanisole | | | | | | |
| 2,6-di-tert-butyl-p-cresol | 0 | 0 | 0 | 0 | 0 | 0 |

TABLE 16
Composition of the fluorine-free cleaning agents

| Cleaning agent | Example | Example | Example | Example | Example | Example |
|---|---|---|---|---|---|---|
| (wt %) | 34 | 35 | 36 | 37 | 38 | 41 |
| Formic acid | 0 | 0 | 0 | 0 | 0 | 0 |
| Boric acid | 2 | 2 | 2 | 2 | 2 | 2 |
| Dimethyl sulfoxide | 40 | 40 | 40 | 40 | 40 | 40 |
| Dimethylacetamide | 0 | 0 | 0 | 0 | 0 | 0 |
| N-methyl pyrrolidone | 0 | 0 | 0 | 0 | 0 | 0 |
| Hydroxylamine | 0 | 0 | 0 | 0 | 0 | 0 |
| Tetramethylammonium | 0 | 0 | 0 | 0 | 0 | 0 |
| hydroxide | | | | | | |
| Triethylamine | 0 | 0 | 0 | 0 | 0 | 0 |
| Ethanolamine | 0 | 0 | 0 | 0 | 0 | 0 |
| Diethylenetriamine | 0 | 0 | 0 | 0 | 0 | 0 |
| Triethylenetetramine | 20 | 20 | 20 | 20 | 20 | 20 |
| Ethylene glycol | 0 | 0 | 0 | 0 | 0 | 2 |
| Glucose | 2 | 2 | 2 | 2 | 2 | 0 |
| 1,2,3-Triazole | 0 | 0 | 0 | 0 | 0 | 0 |
| Catechol | 0 | 0 | 0 | 0 | 0 | 3 |
| Benzotriazole | 3 | 0 | 0 | 0 | 0 | 0 |
| 1,5-dimercaptonaphthalene | 0 | 3 | 0 | 0 | 0 | 0 |
| polyethylene glycol | 0 | 0 | 3 | 0 | 0 | 0 |
| polyimide | 0 | 0 | 0 | 3 | 0 | 0 |
| 2-mercaptopyridine | 0 | 0 | 0 | 0 | 3 | 0 |
| p-Hydroxy benzaldehyde | 0 | 0 | 0 | 0 | 0 | 0 |
| acetoxime | 0 | 0 | 0 | 0 | 0 | 0 |
| Span | 2 | 2 | 2 | 2 | 2 | 2 |
| Dodecylbenzene sulfonic | 0 | 0 | 0 | 0 | 0 | 0 |
| acid | | | | | | |
| Hydroquinone | 0 | 0 | 0 | 0 | 0 | 0 |
| butylated hydroxyanisole | 1 | 1 | 1 | 1 | 1 | 1 |
| 2,6-di-tert-butyl-p-cresol | 0 | 0 | 0 | 0 | 0 | 0 |

The cleaning capability and corrosion rate of the fluorine-free cleaning agents obtained in Examples 19-41 were tested by the test methods described in the above examples. The results are shown in Tables 17-24.

TABLE 17
Cleaning capability test results of the fluorine-
free cleaning agents obtained in Examples 19-23

| | Example | Example | Example | Example | Example |
|---|---|---|---|---|---|
| Cleaning agent | 19 | 20 | 21 | 22 | 23 |
| Removal situation of | Completely | Completely | Completely | Completely | Completely |
| residues on the surface of | removed | removed | removed | removed | removed |
| the wafer after metallic | | | | | |
| aluminum etching | | | | | |
| Removal situation of | Completely | Completely | Completely | Completely | Completely |
| residues on the surface of | removed | removed | removed | removed | removed |
| the wafer after silicon | | | | | |
| nitride etching | | | | | |
| Removal situation of | Completely | Completely | Completely | Completely | Completely |
| residues on the surface of | removed | removed | removed | removed | removed |
| the wafer after silicon | | | | | |
| dioxide etching | | | | | |

TABLE 18
Corrosion rate test results of the fluorine-
free cleaning agents obtained in Examples 19-23

| Cleaning | Example | Example | Example | Example | Example |
|---|---|---|---|---|---|
| agent | 19 | 20 | 21 | 22 | 23 |
| Corrosion | <1 | <1 | <1 | <1 | <1 |
| rate −70° C. | | | | | |
| Surface | Almost no | Almost no | Almost no | Almost no | Almost no |
| morphology | corrosion | corrosion | corrosion | corrosion | corrosion |
| of aluminum | | | | | |

TABLE 19
Cleaning capability test results of the fluorine-free cleaning
agents obtained in Examples 24-28 and Examples 39

| | Example | Example | Example | Example | Example | Example |
|---|---|---|---|---|---|---|
| Cleaning agent | 24 | 25 | 26 | 27 | 28 | 39 |
| Removal | Completely | Completely | Completely | Completely | Completely | Completely |
| situation of | removed | removed | removed | removed | removed | removed |
| residues on | | | | | | |
| the surface | | | | | | |
| of the | | | | | | |
| wafer after | | | | | | |
| metallic | | | | | | |
| aluminum | | | | | | |
| etching | | | | | | |
| Removal | Completely | Completely | Completely | Completely | Completely | Completely |
| situation of | removed | removed | removed | removed | removed | removed |
| residues on | | | | | | |
| the surface | | | | | | |
| of the | | | | | | |
| wafer after | | | | | | |
| silicon | | | | | | |
| nitride | | | | | | |
| etching | | | | | | |
| Removal | Completely | Completely | Completely | Completely | Completely | Completely |
| situation of | removed | removed | removed | removed | removed | removed |
| residues on | | | | | | |
| the surface | | | | | | |
| of the | | | | | | |
| wafer after | | | | | | |
| silicon | | | | | | |
| dioxide | | | | | | |
| etching | | | | | | |

TABLE 20
Corrosion rate test results of the fluorine-free cleaning
agents obtained in Examples 24-28 and Examples 39

| | Example | Example | Example | Example | Example | Example |
|---|---|---|---|---|---|---|
| Cleaning agent | 24 | 25 | 26 | 27 | 28 | 39 |
| Corrosion | <1 | <1 | <1 | <1 | <1 | <5 |
| rate −70° C. | | | | | | |
| Surface | Almost no | Almost no | Almost no | Almost no | Almost no | Almost no |
| morphology of | corrosion | corrosion | corrosion | corrosion | corrosion | corrosion |
| aluminum | | | | | | |

TABLE 21
Cleaning capability test results of the fluorine-free cleaning
agents obtained in Examples 29-33 and Examples 40

| | Example | Example | Example | Example | Example | Example |
|---|---|---|---|---|---|---|
| Cleaning agent | 29 | 30 | 31 | 32 | 33 | 40 |
| Removal | Completely | Completely | Completely | Completely | Completely | Completely |
| situation of | removed | removed | removed | removed | removed | removed |
| residues on | | | | | | |
| the surface | | | | | | |
| of the | | | | | | |
| wafer after | | | | | | |
| metallic | | | | | | |
| aluminum | | | | | | |
| etching | | | | | | |
| Removal | Completely | Completely | Completely | Completely | Completely | Completely |
| situation of | removed | removed | removed | removed | removed | removed |
| residues on | | | | | | |
| the surface | | | | | | |
| of the | | | | | | |
| wafer after | | | | | | |
| silicon | | | | | | |
| nitride | | | | | | |
| etching | | | | | | |
| Removal | Completely | Completely | Completely | Completely | Completely | Completely |
| situation of | removed | removed | removed | removed | removed | removed |
| residues on | | | | | | |
| the surface | | | | | | |
| of the | | | | | | |
| wafer after | | | | | | |
| silicon | | | | | | |
| dioxide | | | | | | |
| etching | | | | | | |

TABLE 22
Corrosion rate test results of the fluorine-free cleaning
agents obtained in Examples 29-33 and Examples 40

| | Example | Example | Example | Example | Example | Example |
|---|---|---|---|---|---|---|
| Cleaning agent | 29 | 30 | 31 | 32 | 33 | 40 |
| Corrosion | <1 | <1 | <1 | <1 | <1 | <5 |
| rate −70° C. | | | | | | |
| Surface | Almost no | Almost no | Almost no | Almost no | Almost no | Almost no |
| morphology of | corrosion | corrosion | corrosion | corrosion | corrosion | corrosion |
| aluminum | | | | | | |

TABLE 23
Cleaning capability test results of the fluorine-free cleaning
agents obtained in Examples 34-38 and Examples 41

| | Example | Example | Example | Example | Example | Example |
|---|---|---|---|---|---|---|
| Cleaning agent | 34 | 35 | 36 | 37 | 38 | 41 |
| Removal | Completely | Completely | Completely | Completely | Completely | Completely |
| situation of | removed | removed | removed | removed | removed | removed |
| residues on | | | | | | |
| the surface | | | | | | |
| of the | | | | | | |
| wafer after | | | | | | |
| metallic | | | | | | |
| aluminum | | | | | | |
| etching | | | | | | |
| Removal | Completely | Completely | Completely | Completely | Completely | Completely |
| situation of | removed | removed | removed | removed | removed | removed |
| residues on | | | | | | |
| the surface | | | | | | |
| of the | | | | | | |
| wafer after | | | | | | |
| silicon | | | | | | |
| nitride | | | | | | |
| etching | | | | | | |
| Removal | Completely | Completely | Completely | Completely | Completely | Completely |
| situation of | removed | removed | removed | removed | removed | removed |
| residues on | | | | | | |
| the surface | | | | | | |
| of the | | | | | | |
| wafer after | | | | | | |
| silicon | | | | | | |
| dioxide | | | | | | |
| etching | | | | | | |

TABLE 24
Corrosion rate test results of the fluorine-free cleaning
agents obtained in Examples 34-38 and Examples 41

| | Example | Example | Example | Example | Example | Example |
|---|---|---|---|---|---|---|
| Cleaning agent | 34 | 35 | 36 | 37 | 38 | 41 |
| Corrosion | <1 | <1 | <1 | <1 | <1 | <5 |
| rate −70° C. | | | | | | |
| Surface | Almost no | Almost no | Almost no | Almost no | Almost no | Almost no |
| morphology of | corrosion | corrosion | corrosion | corrosion | corrosion | corrosion |
| aluminum | | | | | | |

What is claimed is:

1. A fluorine-free cleaning agent, wherein the fluorine-free cleaning agent is a water-based cleaning agent; the fluorine-free cleaning agent comprising water, an organic solvent and an amine compound, wherein;
a mass of the organic solvent is 15%-85% of that of the fluorine-free cleaning agent;
a mass of the amine compound is 5%-50% of that of the fluorine-free cleaning agent; and
the fluorine-free cleaning agent also comprises one or more selected from the group consisting of a corrosion inhibitor, an acid and an alcohol compound.

2. The fluorine-free cleaning agent as claimed in claim 1, wherein the mass of the corrosion inhibitor is 0.1%-10% of that of the fluorine-free cleaning agent;
the mass of the acid is 0.5%-5% of that of the fluorine-free cleaning agent;
the mass of the alcohol compound is 0.5%-10% of that of the fluorine-free cleaning agent; and
the alcohol compound is a dihydric alcohol compound and/or a polyhydric alcohol compound.

3. The fluorine-free cleaning agent as claimed in claim 1, wherein the corrosion inhibitor at least comprises one of a triazole group, an amino group, a hydroxyl group, a carboxyl group or a sulfhydryl group;
the acid is one or more selected from the group consisting of sulfuric acid, nitric acid, hydrochloric acid, phosphoric acid, formic acid, acetic acid, citric acid, boric acid and carbonic acid; and
the alcohol compound is one or more selected from the group consisting of ethylene glycol, glycerol, 1,3-butanediol, 1,2-pentanediol, pentaerythritol, 2,5-hexanediol, polycaprolactone diol, 1,6-hexanediol, sorbitol, neopentyl glycol, 1,4-butanediol, 1,2,6-hexanetriol, xylitol, L-mannitol, D(+)-arabitol, geraniol, dulcitol, 1,2,4-butanetriol, furfuryl alcohol, phytol, dipentaerythritol, L-threitol, L-talitol, glucose, erythritol and xylose.

4. The fluorine-free cleaning agent as claimed in claim 1, wherein the corrosion inhibitor is one or more selected from the group consisting of 1,2,4-triazole, benzotriazole, 1H-1,2,3-triazole, 5-methylbenzotriazole, 5-hydroxybenzotriazole, 1H-1,2,3-triazole-1-amine, 3-cyano-1,2,4-triazole, 1,2,4-triazole-3-carboxamide, 1-ethyl-1H-1,2,3-triazole, 1-phenyl-1H-1,2,4-triazole, 1H-1,2,4-triazole-3-carboxylic acid, 2-phenyl-2H-1,2,3-triazole, 3-methyl-1H-1,2,4-triazole, 3-phenyl-1,2,4-1H-triazole, 4-methyl-1H-1,2,3-triazole, 1H-1,2,3-triazole-4-carboxylic acid, 2H-2-acetic acid-1,2,3-triazole, 3,5-diamino-1,2,4-triazole, methyl 1,2,3-triazole-4-carboxylate, methyl 1,2,4-triazole-3-carboxylate, N,N′-carbonylbis(1,2,3-triazole), 1,4-dimethyl-1H-1,2,3-triazole, methyl 2H-1,2,3-triazole-4-carboxylate, 3,5-diphenyl-1H-1,2,4-triazole, 5-methyl-1H-1,2,4-triazole-3-thiol, 3-amino-5-mercapto-1,2,4-triazole, 3-(1,2,4-triazol-1-yl) benzoic acid, 3-(1,2,4-triazol-1-yl) benzaldehyde, 4-(4H-1,2,4-triazol-3-yl) aniline, 1-hydroxybenzotriazole, 3-(1H-(1,2,3) triazol-4-yl)-benzonitrile, 3-mercapto-1,2,4-triazole, 3-amino-1,2,4-triazole, 3-amino-1H-1,2,4-triazole-5-carboxylic acid, 4-(4H-1,2,4-triazol-4-yl) benzoic acid, 1-hydroxy-7-azobenzotriazole, [1,2,4] triazole [1,5-a] pyridine-6-formaldehyde, [1,2,4] triazolo [1,5-a] pyridine-7-ol, 1-methyl-1,2,3-triazole-5-carboxylic acid methyl ester, 5-cyclohexyl-1H-3-amino-1,2,4-triazole, 4-amino-4H-1,2,4-triazole, 5-amino-2,4-dihydro-[1,2,4] triazol-3-one, 4,5,6,7-tetrahydro-1,2,3-triazolo [1,5-a] pyrazine, 2-mercaptopyridine, 2-mercaptopyrazine, 2-mercaptoimidazole, 2-mercaptothiazole, 2-mercaptonicotinic acid, 3-mercaptobutyric acid, 3-mercaptopropionic acid, 3-mercaptoindole, 4-mercaptopyridine, 4-mercaptouridine, 6-mercaptopurine, 6-mercaptohexanoic acid, beta-mercaptoethylamine, dimercaprol, thionicotinamide, 1,5-dimercaptonaphthalene, 2-mercapto-3-butanol, 2-mercapto-3-pentanone, thiosalicylic acid, 2-mercaptothiazoline, 2-mercaptobenzyl alcohol, 2-methylmercaptoaniline, 3-mercapto-1-hexanol, 3-mercapto-2-butanone, 3-mercapto-2-pentanone, 2-mercaptobenzoic acid, 3-mercaptobenzoic acid, 4-mercaptobenzoic acid, 4-mercaptobenzyl alcohol, 4-mercaptobenzaldehyde, 6-mercaptohexan-1-ol, 6-methylmercaptopurine, 2,4-dimercaptopyrimidine, 2,6-dimercaptopurine, 2-mercaptobenzimidazole, 2-mercaptobenzothiazole, 2-mercaptobenzoxazole, 4-mercaptophenylacetic acid, 3-mercaptohexyl acetate, 3-mercapto-1,2,4-triazole, o-aminophenol, catechol, dopamine, 4-ethylcatechol, 3,4-dihydroxybenzoic acid, nordihydroguaiaretic acid, 2,3-dihydroxypyridine, 2,4-dihydroxyquinoline, 3,4-dihydroxyacetophenone, 2,3-dihydroxyquinoxaline, 3,4-dihydroxybenzonitrile, 1,2-dihydroxynaphthalene, 3,4-dihydroxybenzaldehyde, 5,6-dihydroxyindole, 4-amino-6-hydroxy-2-mercaptopyrimidine, 2-methylmercapto-4-amino-6-hydroxypyrimidine, 2-mercaptobenzyl alcohol, 2-mercaptocytosine, 6-mercapto-1-hexanol, 6-amino-2-mercaptopyrimidine-4-ol, 3-mercapto-1-hexanol, 3-mercapto-1-propanol, 3-mercaptopropionic acid, 2-mercapto-5-methylbenzimidazole, 4,6-dimethyl-2-mercaptopyrimidine, 3-mercapto-3-methyl-1-butanol, 3-mercapto-4-methyl-4H-1,2,4-triazole, 5-methoxy-2-mercaptobenzimidazole, 3-mercaptophenylboronic acid, polyethylene glycol, polyimide, 2-phenyl-4-pentaethylenehexamine-2-ol, 3-amino-5-hydroxypyrazole, 2-amino-3-hydroxyphenazine, 4-amino-3-hydroxybenzoic acid, 3-amino-4-hydroxypyridine, 2′-amino-3′-hydroxyacetophenone, 5-amino-2-hydroxypyridine, 4-amino-6-hydroxypyrimidine, 2-amino-8-hydroxyquinoline, 2-amino-3-hydroxypyridine, 3′-amino-2′-hydroxybiphenyl-3-carboxylic acid, 2-amino-4-hydroxybenzothiazole, 2-acetamido-6-hydroxypurine, 2-amino-N-hydroxypropionamide, 2-amino-N-hydroxypentanamide, 3-amino-5-hydroxypyridine, 4-acetamido-3-hydroxybenzoic acid and 2-amino-4-hydroxy-6-methylpyrimidine.

5. The fluorine-free cleaning agent as claimed in claim 1, wherein the amine compound is one or more selected from the group consisting of methylamine, ethylamine, hydroxylamine, octylamine, triethylamine, acetamide, diethylamine, tert-butylamine, butyramide, dopamine, isobutylamine, isoamylamine, n-propylamine, n-hexylamine, cyclopropylamine, cyclohexylamine, cycloheptylamine, cyclopentylamine, heptylamine, ethanolamine, diethanolamine, diglycolamine, isopropanolamine, triisopropanolamine, diisopropanolamine, N-ethylethanolamine, N-phenylethanolamine, N-acetylethanolamine, N-butyldiethanolamine, N-cyclohexylethanolamine, N-benzyldiethanolamine, N-phenyldiethanolamine, N,N-dibenzylethanolamine, N-tert-butyldiethanolamine, N-tert-butylisopropanolamine, N-methyldiisopropanolamine, 1,6-hexanediamine, 1,2-propanediamine, 1,3-propanediamine, 1,4-butanediamine, 1,8-octanediamine, triethylenediamine, tri-n-dodecylamine, diethylenetriamine, adipamide, maleic diamine, 2-octyldodecylamine, N-ethylethylenediamine, N-methylethylenediamine, N-benzylethylenediamine, N-phenylethylenediamine, spermine, N-acetylethylenediamine, pentaethylenehexamine, tetraethylenepentamine, 1H-pyrazole-3,5-diamine, 3-diethylaminopropylamine, 3-dimethylaminopropylamine, N-butylethylenediamine, N-isopropylethylenediamine, N-methyl-p-phenylenediamine, tetramethylmethanediamine, tetrabutylammonium hydroxide, tetraethylammonium hydroxide, tetrapropylammonium hydroxide, tetramethylammonium hydroxide, 2-[(hydroxymethyl) amino] ethanol, benzyltrimethylammonium hydroxide, N-(benzylcarbonyloxy) hydroxylamine and N,N-dibenzylhydroxylamine; the organic solvent is one or more selected from the group consisting of 2-methoxyethanol, 2-ethoxyethanol, 2-butoxyethanol, diethylene glycol monomethylether, butyldiglycol, dipropylene glycol butyl ether, tripropylene glycol butyl ether, 1-Methoxy-2-propyl acetate, N-methylpyrrolidone, N,N-dimethylformamide, N,N-dimethylacetamide, N,N-diethylpropionamide, N,N-dimethylpropionamide, N,N-diethylacetamide, sulfolane, dimethyl sulfoxide and 1,4-butyrolactone.

6. The fluorine-free cleaning agent as claimed in claim 1, wherein the fluorine-free cleaning agent also comprises a stabilizer; the mass of the stabilizer is 2%-20% of that of the fluorine-free cleaning agent; and the stabilizer is one or more selected from the group consisting of ethanol, 2-hydroxypyridine, 4-hydroxypyridine, p-hydroxybenzaldehyde, salicylic acid, thiosalicylic acid, 2,6-dimethyl-3-hydroxypyridine, 2,3-dihydroxypyridine, 5-amino-2-hydroxypyridine, gelatin, tris(hydroxymethyl) aminomethane, 3-morpholinopropanesulfonic acid, 4-hydroxyethylpiperazine ethanesulfonic acid, ammonium borate, ammonium acetate, ammonium formate, ammonium phosphate, ammonium dihydrogen phosphate, ammonium citrate and barbituric acid;
wherein the fluorine-free cleaning agent also comprises a surfactant; the mass of the surfactant is 0.5%-10% of that of the fluorine-free cleaning agent; and the surfactant is one or more selected from the group consisting of 3,5-dimethyl-1-hexyne-3-ol, laureth phosphate, coconut diethanolamide, cocamidopropyl betaine, cocamidopropyl hydroxysultaine, lauramidopropyl hydroxysultaine, acetoxime, lauramidopropyl amine oxide, monoglyceride, Span, dodecylbenzene sulfonic acid and polyoxyl-15 hydroxystearate.

7. The fluorine-free cleaning agent as claimed in claim 1, wherein the fluorine-free cleaning agent also comprises an antioxidant; the mass of the antioxidant is 0.1%-10% of that of the fluorine-free cleaning agent; and the antioxidant is one or more selected from the group consisting of butylated hydroxyanisole, 2,6-di-tert-butyl-p-cresol, hydroquinone, D-isoascorbic acid, sorbitol, phytic acid, chitosan and chitooligosaccharide.

8. A preparation method for the fluorine-free cleaning agent as claimed in claim 1, comprising:
mixing water, an organic solvent, an amine compound and one or more of a corrosion inhibitor, an acid and an alcohol compound to obtain the fluorine-free cleaning agent.

9. Use of the fluorine-free cleaning agent as claimed in claim 1 in the field of electronic industry including semiconductor integrated circuits.

10. A cleaning method, comprising: cleaning a wafer by a soaking method or a single-wafer clean method using the fluorine-free cleaning agent as claimed in claim 1.

11. Use of the fluorine-free cleaning agent as claimed in claim 2 in the field of electronic industry including semiconductor integrated circuits.

12. Use of the fluorine-free cleaning agent as claimed in claim 3 in the field of electronic industry including semiconductor integrated circuits.

13. Use of the fluorine-free cleaning agent as claimed in claim 4 in the field of electronic industry including semiconductor integrated circuits.

14. Use of the fluorine-free cleaning agent as claimed in claim 5 in the field of electronic industry including semiconductor integrated circuits.

15. Use of the fluorine-free cleaning agent as claimed in claim 6 in the field of electronic industry including semiconductor integrated circuits.

16. Use of the fluorine-free cleaning agent as claimed in claim 7 in the field of electronic industry including semiconductor integrated circuits.

17. A cleaning method, comprising: cleaning a wafer by a soaking method or a single-wafer clean method using the fluorine-free cleaning agent as claimed in claim 2.

18. A cleaning method, comprising: cleaning a wafer by a soaking method or a single-wafer clean method using the fluorine-free cleaning agent as claimed in claim 3.

19. A cleaning method, comprising: cleaning a wafer by a soaking method or a single-wafer clean method using the fluorine-free cleaning agent as claimed in claim 4.

20. A cleaning method, comprising: cleaning a wafer by a soaking method or a single-wafer clean method using the fluorine-free cleaning agent as claimed in claim 5.
